(19) United States
(12) Patent Application Publication
(10) Pub. No.: US 2026/0371654 A1
(43) Pub. Date: Nov. 19, 2026

(54) SELF-ALIGNED ISOTROPIC MD FORMATION WITHOUT HARD MASK ON METAL GATE

(71) Applicant: Taiwan Semiconductor Manufacturing Co., Ltd., Hsinchu (TW)

(72) Inventors: Chun-Yuan CHEN, Hsinchu (TW); Meng-Huan JAO, Hsinchu (TW); Huan-Chieh SU, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/753,914

(22) Filed: Jul. 24, 2026

Related U.S. Application Data
(63) Continuation of application No. 18/741,648, filed on Jun. 12, 2024.

(51) Int. Cl. H10D 30/67; H10D 30/01; H10D 30/43; H10D 62/10

(52) U.S. Cl. CPC H10D 30/6735; H10D 30/014; H10D 30/43; H10D 30/6713; H10D 30/6729; H10D 30/6757; H10D 62/121

(57) ABSTRACT

An integrated circuit includes a first transistor having a plurality of stacked channels and a source/drain region in contact with the stacked channels of the first transistor. The integrated circuit includes a second transistor including a plurality of stacked second channels in contact with the source/drain region and a second gate metal above the second channels. A dielectric spacer layer is positioned on sidewalls of the first and second gate metal. A recess is formed in the source/drain region in a self-aligned manner utilizing the dielectric spacer layer as a mask. A source/drain contact is formed in the recess equidistant between the first gate metal and the second gate metal.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Nanostructure transistors can assist in increasing computing power because the nanostructure transistors can be very small and can have improved functionality over convention transistors. Source and drain regions may be coupled to the nanostructures. It can be difficult to form source and drain regions with desired characteristics.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1L are perspective and cross-sectional views of an integrated circuit at various stages of processing, in accordance with some embodiments.

FIG. 2 is a cross-sectional view of an integrated circuit, in accordance with some embodiments.

FIG. 3 is a cross-sectional view of an integrated circuit, in accordance with some embodiments.

FIG. 4 is a cross-sectional view of an integrated circuit, in accordance with some embodiments.

FIG. 5 is a cross-sectional view of an integrated circuit, in accordance with some embodiments.

FIG. 6 is flow-diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure, or characteristic described in connection with the embodiment is included in at least some embodiments. Thus, the appearances of the phrases “in some embodiments”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit with nanostructure transistors having improved performance. The nanostructure transistors each have a plurality of stacked channels formed over a substrate. Each nanostructure transistor includes source/drain regions in contact with the channels. Source/drain contacts are formed in a self-aligned manner within recesses formed in the source/drain regions. The self-aligned process utilizes dielectric spacer layers on sidewalls of engaging gate metals as a mask to form the recesses. The source/drain contacts are then formed in the recesses. Due to the self-aligned process, the source/drain contacts are symmetrically positioned between adjacent gate metals.

The configuration of the source/drain regions and the source/drain contacts provides several benefits. First, the self-aligned process avoids the possibility that the source/drain contact with short circuit with the gate metals. Second, the self-aligned process results in very relaxed photolithography standards when forming source/drain contacts. An isotropic etching process can be used due to the relaxed photolithography standards. Furthermore, source/drain isolation structures can be formed prior to forming the source/drain contacts. These factors collectively result in better wafer yields, integrated circuits with better electrical performance, and fewer scrapped wafers.

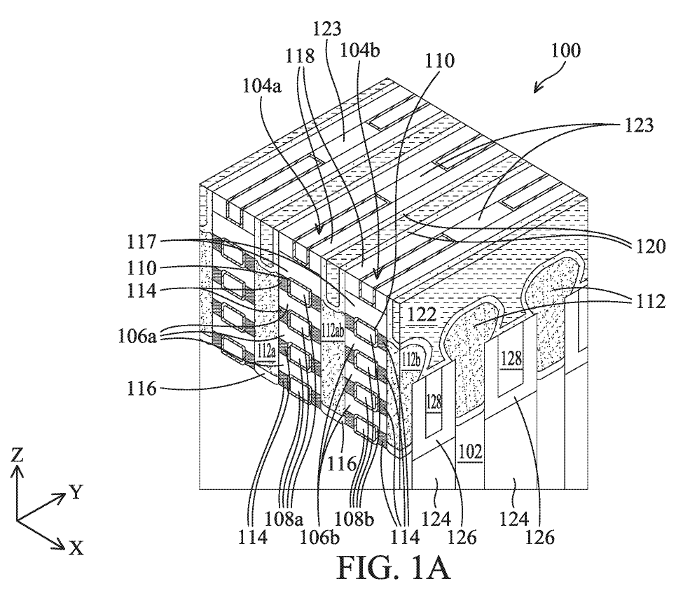

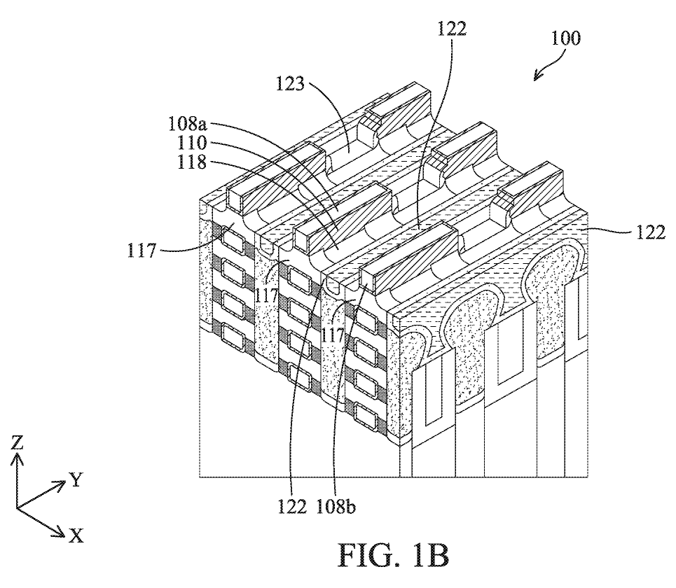

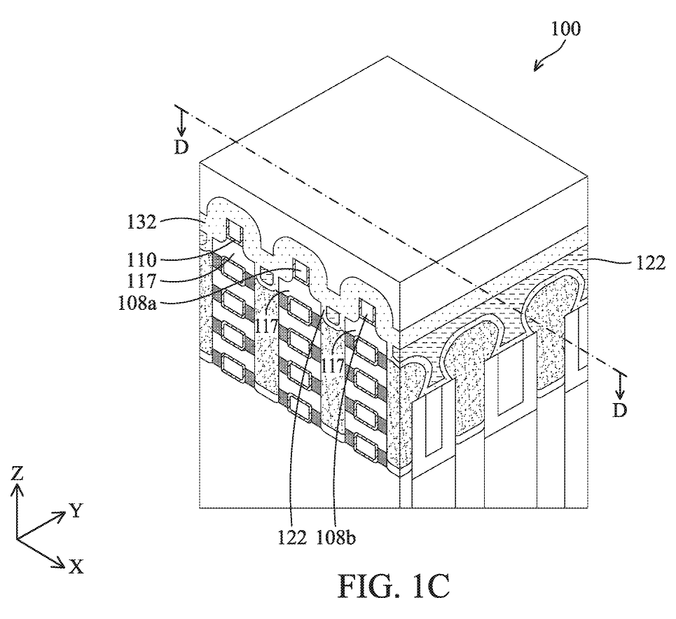

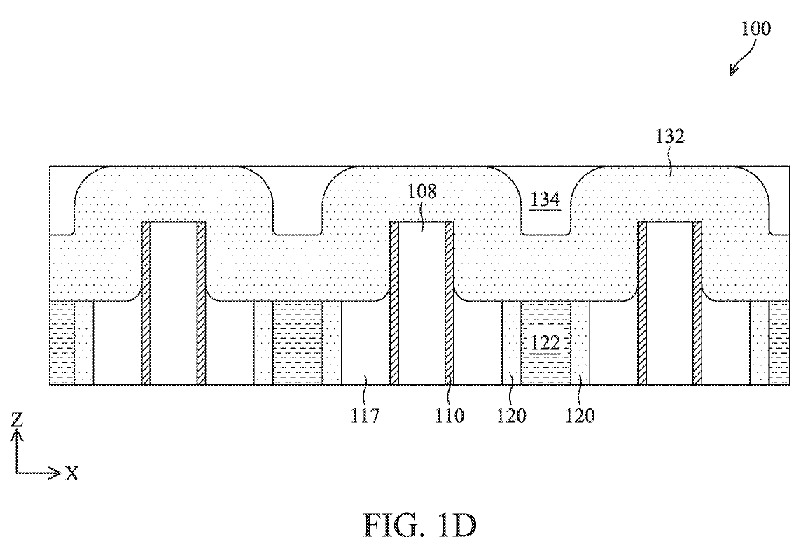

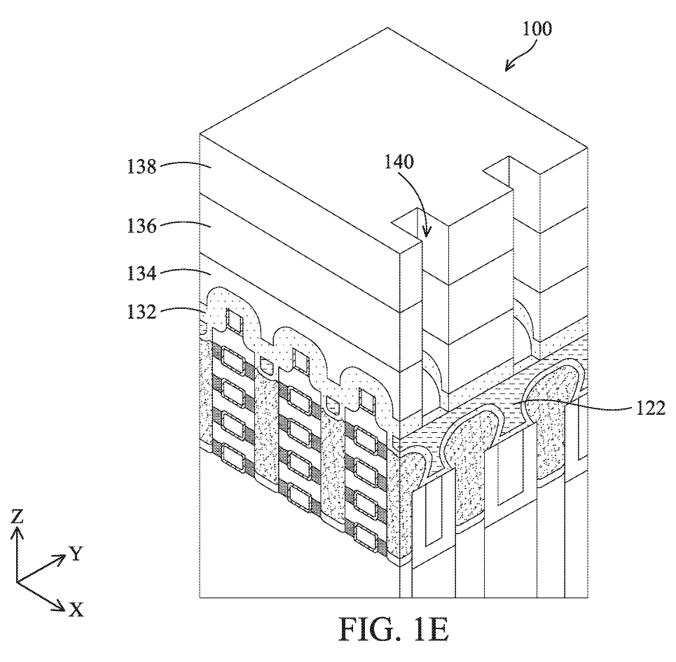

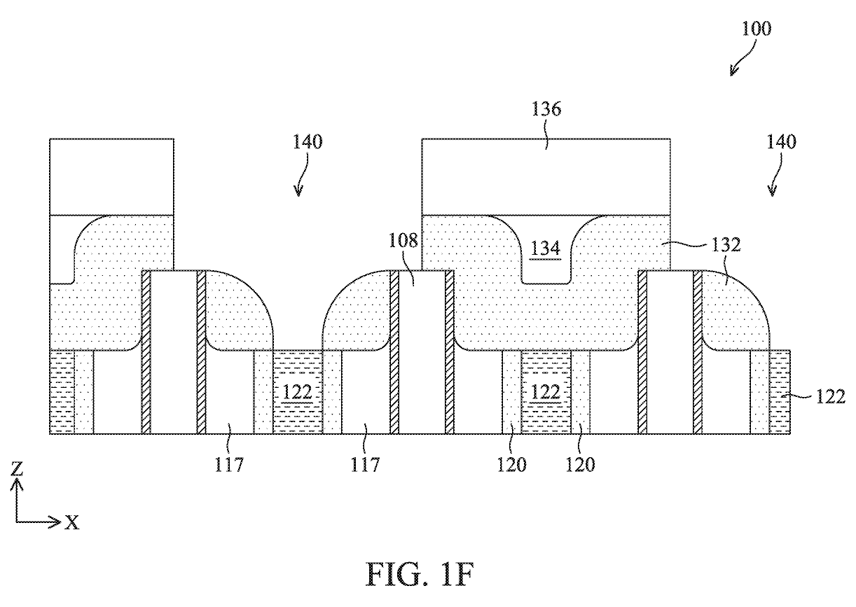

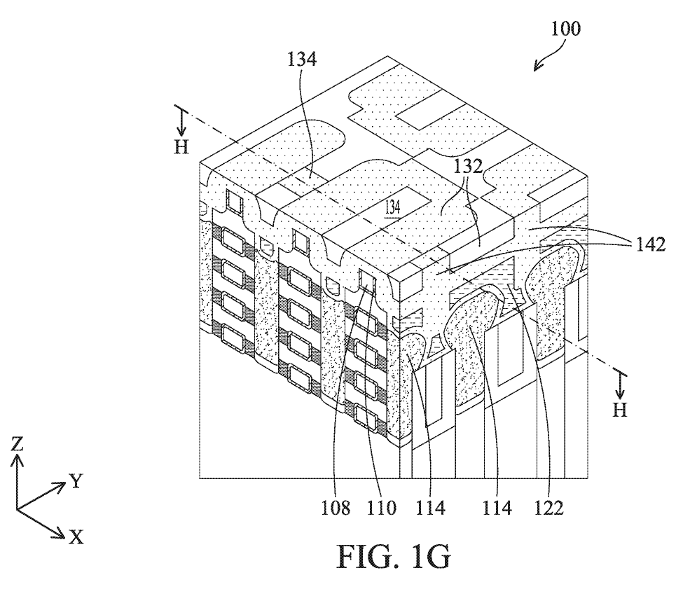

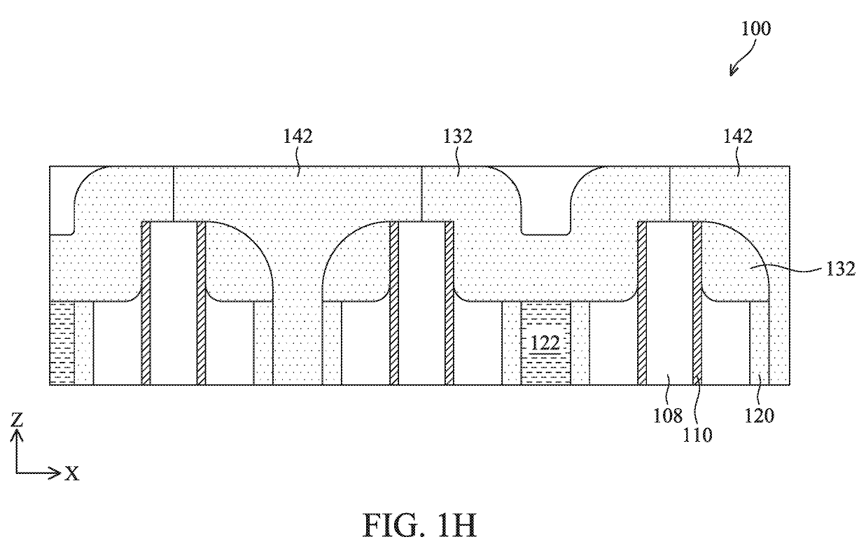

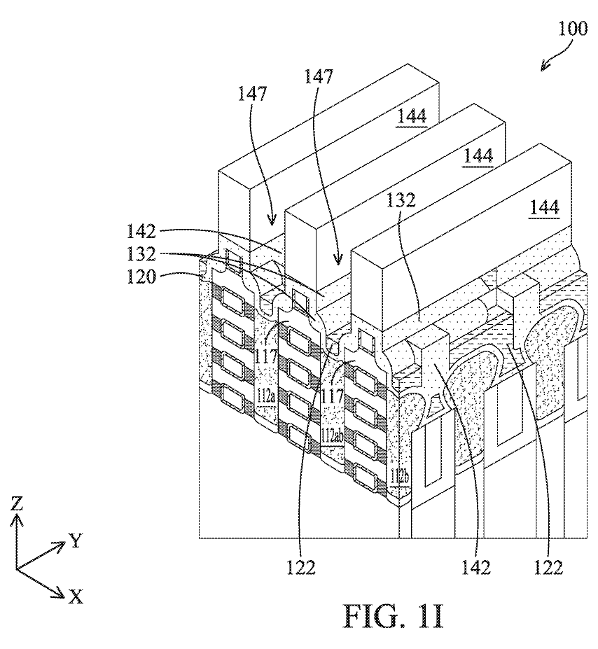

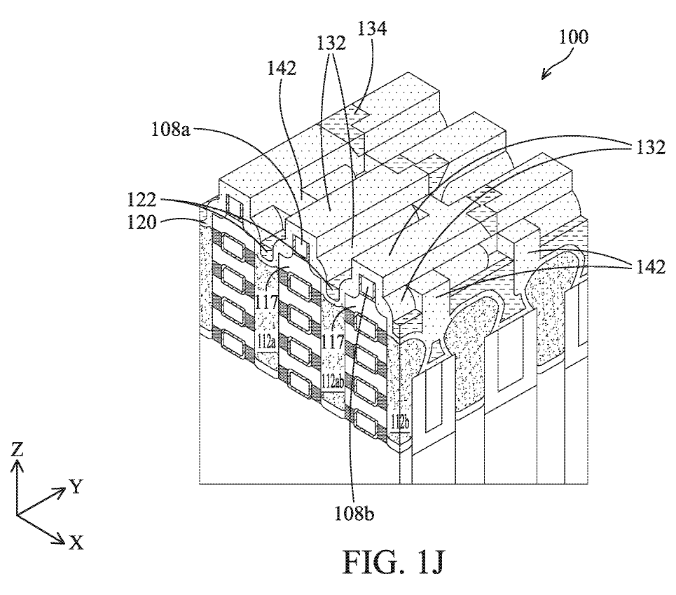

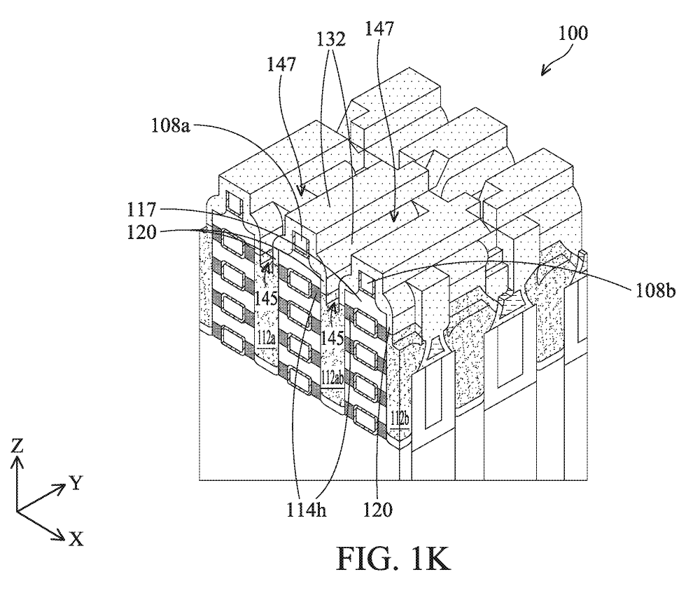

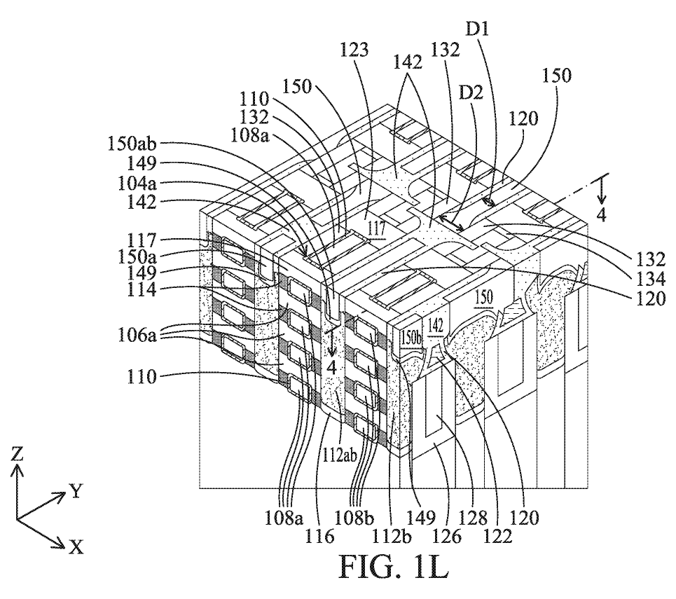

FIGS. 1A-1L are perspective and cross-sectional views of an integrated circuit 100 at various stages of processing, according to some embodiments. FIGS. 1A-1L illustrate an exemplary process for producing an integrated circuit that includes nanostructure transistors. FIGS. 1A-1L illustrate how these transistors can be formed in a simple and effective process in accordance with principles of the present disclosure. Other process steps and combinations of process steps can be utilized without departing from the scope of the present disclosure. The transistors can include gate all around transistors, multi-bridge transistors, nanostructure transistors, nanowire transistors, or other types of nanostructure transistors.

FIG. 1A is a cross-sectional view of an integrated circuit 100, in accordance with some embodiments. The integrated circuit 100 includes a semiconductor substrate 102. The integrated circuit 100 includes a first transistor 104a and a second transistor 104b. Before providing a detailed description of the components of the transistors 104a/104b and other structures of the integrated circuit 100, a brief overview of the general components and basic function of each of the transistors 104a and 104b will be provided.

The transistor 104a includes a plurality of vertically stacked channels 106a. The transistor 104a includes a gate metal 108a corresponding to a gate electrode wrapping around each of the channels 106a. A gate dielectric 110 is positioned between the channels 106a and the gate metal 108a. The transistor 104a includes a source/drain region 112a and a source/drain region 112ab. The channels 106a extend in the X direction between the source/drain region 112a and the source/drain region 112ab.

The transistor 104b includes a plurality of vertically stacked channels 106b. The transistor 104b includes a gate metal 108b corresponding to a gate electrode wrapping around each of the channels 106b. A gate dielectric 110 is positioned between the channels 106b and the gate metal 108b. The transistor 104b includes the source/drain region 112ab and a source/drain region 112b. The channels 106b extend in the X direction between the source/drain region 112b and the source/drain region 112b. The source/drain region 112ab corresponds to a shared source/drain region of the transistors 104a and 104b.

Some reference numbers shown in the Figures include a suffix “a” “b”, or “ab” to distinguish between the transistors 104a and 104b and their components. In some cases herein, the description may omit the suffixes when given details are not particular to either of the transistors but can correspond to the components of either or both transistors. As another example, FIG. 1A illustrates channels 106a of the transistor 104a, and channels 106b of the transistor 104b. However, when the description may omit the suffixes “a” and “b” and simply refer to channels 106 when the description applies to both the channels 106a and the channels 106b.

The channels 106 may correspond to semiconductor nanostructures and may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

The channels 106 may also be termed semiconductor nanosheets, though other types of semiconductor nanostructures can be utilized without departing from the scope of the present disclosure. The channels 106 can include a monocrystalline semiconductor material such as silicon, silicon germanium, or other semiconductor materials. The channels 106 may be an intrinsic semiconductor material or may be a doped semiconductor material. The semiconductor nanostructures may include nanosheets, nanowires, or other types of nanostructures. The channels 106 may have a thickness in the Z direction between 2 nm and 5 nm. The channels 106 may have a width in the X direction between 5 nm and 15 nm. Other materials and dimensions can be utilized for the channels 106 without departing from the scope of the present disclosure.

While FIG. 1A illustrates that each transistor 104 includes three stacked channels 106, in practice, different numbers of stacked channels 106 can be utilized without departing from the scope of the present disclosure. In some embodiments, each transistor 104 may include only a single channel 106.

The gate metal 108 includes one or more conductive materials. The gate metal 108 can include one or more of tungsten, aluminum, titanium, tantalum, copper, gold, or other conductive materials. The gate metal 108 can surround the channels 106 such that each channel 106 extends through the gate metal 108 between the source/drain regions 112. The gate metal 108 can include a plurality of gate metal layers including liner layers, work function layers, and gate fill layers. The gate metal 108 includes a top portion above the highest channel 106.

A gate dielectric 110 surrounds the channels 106 and acts as a dielectric sheath between the channels 106 and the gate metal 108. Although a single gate dielectric layer 110 is shown, in practice, the gate dielectric layer 110 can include an interfacial gate dielectric layer and a high K gate dielectric layer. The interfacial gate dielectric layer is on the surfaces of the channels 106 and on other surfaces. The interfacial gate dielectric layer is deposited on all exposed surfaces of the channels 106. The interfacial gate dielectric layer laterally surrounds the channels 106. The interfacial gate dielectric layer can include a dielectric material such as silicon oxide, silicon nitride, or other suitable dielectric materials. The interfacial gate dielectric layer can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer can be formed by a thermal oxidation process, a chemical vapor deposition (CVD) process, or an atomic layer deposition (ALD) process. The interfacial gate dielectric layer can have a thickness between 0.5 nm and 2 nm. Other materials, deposition processes, and thicknesses can be utilized for the interfacial gate dielectric layer without departing from the scope of the present disclosure.

The high-K gate dielectric layer has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer may be formed by CVD, ALD, or any suitable method. Other thicknesses, deposition processes, and materials can be utilized for the high-K dielectric layer without departing from the scope of the present disclosure.

Each transistor 104 includes inner spacers 114. The inner spacers 114 serve to electrically isolate the channels 106 and the source/drain regions 112 from the gate metal 108. The inner spacers 114 can include a low K dielectric material such as SiO2, SiN, SiCN, SiOC, SiOCN, or other suitable dielectric materials.

FIG. 1A also illustrates a dielectric helmet structure 117 between a highest channel 106 and the top portion of the gate metal 108. The dielectric helmet structure 117 can include a dielectric material such as silicon oxide, silicon nitride, silicon oxynitride (SiON), SiOCN, SiCN, fluorine-doped silicate glass (FSG), or a low-K dielectric material, or other suitable materials. In some embodiments, the dielectric helmet structures 117 are not present. In these cases, the upper portion of the gate metal 108 is separated from the highest channel 106 only by the gate dielectric layer 110.

In one embodiment, the integrated circuit 100 includes a bottom dielectric 116. The bottom dielectric 116 is positioned between the substrate 102 and the source/drain layers 112. The bottom dielectric layer 116 abuts the lowest inner spacers 114 of each transistor 104. The bottom dielectric 116 can include a dielectric material such as silicon oxide, silicon nitride, silicon oxynitride (SiON), SiOCN, SiCN, fluorine-doped silicate glass (FSG), or a low-K dielectric material, or other suitable materials.

Each transistor 104 includes sidewall spacers 118 adjacent to the upper portion of the gate metal 108. The sidewall spacers 118 are separated from the upper portion of the gate metal 108 by the gate dielectric 110. In one embodiment, the sidewall spacers 118 can include a dielectric material such as silicon oxide, silicon nitride, silicon oxynitride (SiON), SiOCN, SiCN, fluorine-doped silicate glass (FSG), or a low-K dielectric material, or other suitable materials. The sidewall spacers 118 may be termed sacrificial sidewall spacers as they are, subsequently, at least partially removed and replaced, in accordance with some embodiments.

A dielectric liner layer 120 lines the sidewalls of the sidewall spacers 118 and the sidewalls of the dielectric helmet structures 117. At the stage of processing shown in FIG. 1A, the dielectric liner layer also lines the top surface of the source/drain regions 112. The dielectric liner layer 120 can include a dielectric material such as silicon oxide, silicon nitride, silicon oxynitride (SiON), SiOCN, SiCN, fluorine-doped silicate glass (FSG), or a low-K dielectric material, or other suitable materials. The dielectric liner layer 120 may correspond to an etch-stop dielectric layer.

The source/drain regions 112 is a thin layer of semiconductor material. The semiconductor material of the source/drain layer 112 can be the same or different than the semiconductor material of the channels 106. The source/drain layer 112 can include silicon, silicon germanium, or other suitable semiconductor materials. The source/drain layer 112 is doped with dopant species. In the case of an N-type transistor, the source/drain layer 112 can be doped with phosphorus, arsenic, or other suitable dopant species. In the case of a P-type transistor, the source/drain layer 112 can be doped with boron, aluminum, or other suitable dopant species. The source/drain layer 112 can have a dopant concentration between 3E19/cm^3 and 7E19/cm^3.

The source/drain layer 112 can be formed with an epitaxial growth process from the channels 106. The source/drain layer 112 extends from the bottom dielectric 116 to a level higher than the top surface of the top channel 106. Other thicknesses, materials, and processes can be utilized without departing from the scope of the present disclosure.

In FIG. 1A, the interlevel dielectric layer 122 has been formed. The interlevel dielectric layer 122 can include one or more of silicon oxide, silicon nitride, silicon oxynitride (SiON), SiOCN, SiCN, fluorine-doped silicate glass (FSG), or other suitable dielectric materials. The dielectric liner layer 120 has also been formed prior to deposition of the interlevel dielectric layer 122. The dielectric liner layer 120 can correspond to an etch stop layer and can include silicon oxide, silicon nitride, silicon oxynitride (SiON), SiOCN, SiCN, fluorine-doped silicate glass (FSG), or other suitable dielectric materials.

In FIG. 1A, gate isolation structures 123 have been formed. The gate isolation structures are utilized to electrically isolate gate metals 108 of transistors that are adjacent to each other in the Y direction. The gate isolation structures 123 can include silicon oxide, silicon nitride, silicon oxynitride (SiON), SiOCN, SiCN, fluorine-doped silicate glass (FSG), or other suitable dielectric materials. The gate isolation structures 123 may also be termed “cut metal gate” (CMG) structures formed in a CMG process that electrically isolates gate structures of adjacent transistors. The cut metal gate process can include utilizing a photolithography process to form trenches through the integrated circuit 100 to remove selected portions of gate structures in order to electrically isolate gate structures of adjacent transistors. The gate isolation structures 123 can be formed in the trenches to isolate gate structures from each other.

In some embodiments, trench isolation regions 124 have been formed in the substrate 102. The trench isolation regions 124 can correspond to shallow trench isolation regions. The trench isolation regions include a dielectric material. The trench isolation regions 124 can include silicon oxide, silicon nitride, silicon oxynitride (SiON), SiOCN, SiCN, fluorine-doped silicate glass (FSG), or other suitable dielectric materials.

In some embodiments, the integrated circuit 100 includes dielectric fin structures including a dielectric layer 126 and a dielectric layer 128 formed on the trench isolation regions 124 between source/drain regions 112 spaced apart from each other in the Y direction. The dielectric layer 126 is positioned directly on top of the trench isolation region 124 and abuts sidewalls of the substrate 102, the bottom dielectric 116, and the source/drain regions 112. The dielectric layer 126 forms a U shape. The dielectric layer 281 fills the gap in the U shape of the dielectric layer 126. In some embodiments, the dielectric layer 126 can include silicon oxide, silicon nitride, silicon oxynitride (SiON), SiOCN, SiCN, fluorine-doped silicate glass (FSG), or other suitable dielectric materials. The dielectric layer 128 can include silicon oxide, silicon nitride, silicon oxynitride (SiON), SiOCN, SiCN, fluorine-doped silicate glass (FSG), or other suitable dielectric materials. In practice, the dielectric layers 126 and 128 are separate materials. In one example, the dielectric layer 128 is silicon oxide and the dielectric layer 126 includes a nitride of silicon. The dielectric liner layer 120 is positioned on top surfaces of the dielectric layers 126 and 128.

In some embodiments, a basic process for forming the structure shown in FIG. 1A can include forming a stack of channel layers of sacrificial semiconductor layers ultimately stacked over the substrate 102. The stack of channel layers is eventually patterned to form the channels 106. The stack of sacrificial semiconductor layers is eventually removed and the gate metal 108 and the spacers 118 are formed in the place. The dummy gate structure is formed over the stack layers includes a polysilicon dummy gate and gate spacers. Source/drain trenches are then formed in the stacked channel layers and sacrificial semiconductor layers. Recesses are formed in the sacrificial semiconductor layers and the inner spacers 114 are formed in the recesses. The bottom dielectric 116 is then formed over the substrate at the bottom of the source/drain trenches. The source/drain layer 112 are then formed in the source/drain trenches. The dielectric liner layer 120 and the interlevel dielectric layer 122 are then formed, as will be described in more detail below. The sacrificial semiconductor layers are then entirely removed and replaced by the gate dielectric 110 and the gate metal 108.In FIG. 1A, a chemical mechanical planarization (CMP) process has been performed. The CMP process reduces the height of and planarizes the upper portions of the gate metal 108, the sidewall spacers 118, the dielectric liner layer 120, the interlevel dielectric layer 122, and the gate isolation dielectric 123. This leaves the structure shown in FIG. 1A.

In FIG. 1B, an etching process has been performed. The etching process etches back the sidewall spacers 118, the dielectric liner layer 120, the interlevel dielectric layer 122, and the gate isolation structures 123. The etching process also recesses the top surface of the dielectric helmet structures 117. The etching process can include a single etching step or multiple etching steps. The etching process can include one or more of a wet etch, dry etch, or other types of etching processes.

The result of the etching processes is that the gate dielectric 110 on the sidewalls of the upper portions of the gate metal 108 is exposed. Furthermore, a recess is formed in the dielectric helmet structure 117 such that the exposed upper surface of the dielectric helmet structure 117 is lower than the portion of the upper surface of the dielectric helmet structure 117 that is not exposed (i.e., the portion directly below the upper portion of the gate metal 108).

In FIG. 1C, a dielectric spacer layer 132 has been deposited. The dielectric layer 132 is deposited in a conformal manner on the gate dielectric 110 on the sidewalls of the upper portion of the gate metal 108, on the exposed top surface of the upper portion of the gate metal 108, on the recessed surface of the dielectric helmet structures 117, on the exposed portions of the dielectric liner layer 122, and on the exposed portions of the interlevel dielectric layer 122. The dielectric layer 132 can be deposited by a chemical vapor deposition (CVD) process, by an atomic layer deposition (ALD) process, by a physical vapor deposition (PVD) process, or by any suitable dielectric process. The dielectric spacer layer 132 can include one or more of silicon oxide, silicon nitride, silicon oxynitride (SiON), SiOCN, SiCN, fluorine-doped silicate glass (FSG), or other suitable dielectric materials. In one example, the dielectric spacer layer 132 includes silicon nitride. The dielectric spacer layer 132 may have a different material than the sidewall spacers 118. For example, the dielectric spacer layer 132 may include SiN, while the sidewall spacers include SiON, SiOCN, or SiCN. Alternatively, the dielectric spacer layer 132 may have a same material as the sidewall spacers 118.

In FIG. 1C, an interlevel dielectric layer 134 has been formed on the dielectric spacer layer 132. The interlevel dielectric layer 134 can include one or more of silicon oxide, silicon nitride, silicon oxynitride (SiON), SiOCN, SiCN, fluorine-doped silicate glass (FSG), or other suitable dielectric materials. The interlevel dielectric layer 134 can be formed by chemical vapor deposition (CVD), atomic layer deposition (ALD), or physical vapor deposition (PVD). Other materials and processes can be utilized for the interlevel dielectric layer 134 without departing from the scope of the present disclosure. In an example in which the dielectric spacer layer 132 includes silicon nitride, the interlevel dielectric layer 134 may include silicon oxide.

In some embodiments, after deposition of the interlevel dielectric layer 134, an etchback process is performed. The etchback process reduces the height of the interlevel dielectric layer 134. The etchback process can include a wet etch, a dry etch, or any suitable etching process.

FIG. 1D is an enlarged cross-sectional view of a portion of the integrated circuit 100 at the stage of processing shown in FIG. 1C, in accordance with some embodiments. The cross-sectional view of FIG. 1D is taken along cut lines D in FIG. 1C. The cross-sectional view of FIG. 1D illustrates the dielectric spacer layer 132 covering exposed surfaces of the dielectric liner layer 120, the gate dielectric 110, the gate metal 108, the interlevel dielectric layer 122, and the dielectric helmet structures 117.

In FIG. 1E, mask layers 136 and 138 have been deposited on the interlevel dielectric layer 134, in accordance with some embodiments. In some embodiments, the mask layer 138 is a layer of photoresist. In some embodiments, the mask layer 136 is a layer of photoresist or is a mask layer of dielectric material. The mask layer 136 can include silicon oxide, silicon nitride, silicon oxynitride (SiON), SiOCN, SiCN, fluorine-doped silicate glass (FSG), or other suitable dielectric materials.

In FIG. 1E, the mask layers 136 and 138 of the patterned to form trenches 140. The mask layers 136 and 138 can be patterned in accordance with a photolithography process or in some other manner. The trenches 140 are utilized to form source/drain isolation structures. The source/drain isolation structures are utilized to electrically isolate source/drain contacts of transistors 104 spaced apart from each other in the Y direction. At the stage of processing shown in FIG. 1E, the material of the source/drain contacts is not yet been deposited. However, as will be described in more detail below, the pattern of the trenches 140 will assist in formation of the source/drain isolation structures.

In FIG. 1E, an etching process has been performed to remove portions of the interlevel dielectric layer 134 and portions of the dielectric spacer layer 132 exposed in the trenches 140. Removal of the portions of the interlevel dielectric layer 134 and the dielectric spacer layer 132 exposes portions of the dielectric spacer layer 132. Removal of the portions of the interlevel dielectric layer 134 and the dielectric spacer layer 132 assists in formation of the source/drain isolation structures, as will be described in more detail below.

FIG. 1F is an enlarged cross-sectional view of a portion of the integrated circuit 100 at the stage of processing shown in FIG. 1E, in accordance with some embodiments. The cross-section is taken along cut lines D shown in FIG. 1D. The view of FIG. 1F illustrates the trenches 140 that have removed the exposed portions of the interlevel dielectric layer 134 and portions of the dielectric spacer layer 132 to expose portions of the interlevel dielectric layer 122. The view of FIG. 1F further illustrates that the etching process described in relation to FIG. 1E etches the dielectric spacer layer 132 selectively in the downward direction and is performed for a selected duration of time. The result is that portions of the dielectric spacer layer 132 that are relatively thin in the Z direction are entirely removed, while portions of the dielectric spacer layer 132 that were relatively thick in the Z direction only partially removed. Thus, a portion of the gate metal 108 is exposed in the trenches 140, in addition to expose portions of the interlevel dielectric layer 122.

In FIG. 1G, source/drain isolation structures 142 have been formed in the trenches 140, in accordance with some embodiments. Formation of the source/drain isolation structures 142 includes depositing a layer of dielectric material by CVD, PVD, ALD, or another suitable deposition process. The dielectric material of the source/drain isolation structures can include silicon oxide, silicon nitride, silicon oxynitride (SiON), SiOCN, SiCN, fluorine-doped silicate glass (FSG), hafnium oxide, zirconium oxide, or other suitable dielectric materials. The source/drain isolation structures 142 fill the trenches 140 and, thus, are positioned on the exposed surfaces of the interlevel dielectric layer 122, the dielectric spacer layer 132, the gate metal 108, the gate dielectric 110, the dielectric liner layer 122, and any other exposed surfaces.

Prior to deposition of the dielectric material for the source/drain isolation structures 142, a further etching process is performed to remove additional material of the interlevel dielectric layer 122 exposed in the trenches 140. Accordingly, the source/drain isolation structures 142 extend downward into the interlevel dielectric layer 122 between upper portions of source/drain regions 112. This is more readily apparent in view of FIG. 1H, described further below.

After deposition of the layer of dielectric material for the source/drain isolation structures 142, a CMP process has been performed. The CMP process reduces the height and planarizes the top surfaces of the interlevel dielectric layer 134, the dielectric spacer layer 132, and the source/drain isolation structures 142.

After the CMP process, the source/drain isolation structures 142 have the form shown in FIG. 1G. The source/drain isolation structures 142 may also be called cut metal drain (CMD) structures. The source/drain isolation structures 142 are utilized to electrically isolate source/drain contacts of selected transistors spaced apart from each other in the Y direction. The pattern of the source/drain isolation structures 142 is selected based on the desired circuit layout and interconnectivity of transistors 104 formed in the integrated circuit 100. A further benefit of the process to form the source/drain isolation structures 142 is that there is substantially no risk of peeling of the source/drain isolation structures 142 of adjacent layer such as the interlevel dielectric layer 134 and the dielectric spacer layer 132. Accordingly, formation of the source/drain isolation structures 142 helps ensure proper function of the integrated circuit 100.

FIG. 1H is an enlarged cross-sectional view of a portion of the integrated circuit 100 at the stage of processing shown in FIG. 1G, in accordance with some embodiments. The cross-section is taken along cut lines H shown in FIG. 1G. The cross-sectional view of FIG. 1H illustrates that the source/drain isolation structures 142 extend downward into the remove portions of the interlevel dielectric layer 122. The source/drain isolation structures 140 to cover exposed surfaces of the gate electrode 108, the gate dielectric 110, the dielectric liner layer 120, and the dielectric spacer layer 132.

In FIG. 1I, a mask layer 144 has been deposited, in accordance with some embodiments. The mask layer 144 is initially deposited on the top surfaces of the dielectric spacer layer 132, the interlevel dielectric layer 134, and the source/drain isolation structures 142. The mask layer 144 can include a photoresist or other type of dielectric layer. The mask layer 144 has been patterned with a photolithography process to form trenches 147. The trenches 147 correspond to the location at which a material for source/drain contacts will be deposited.

Due to the formation of the dielectric spacer layer 132, the dielectric liner layer 120, the interlevel dielectric layer 134, and the source/drain isolation structures 142, the trenches 147 can be formed with relatively relaxed alignment standards. This is because subsequent etching processes to expose the source/drain regions 112 will result in self-aligned openings of the evenly spaced between adjacent portions of the gate metal 108 of adjacent transistors 104, as will be described in more detail below.

In FIG. 1I, after patterning of the mask layer 144, an etching process is performed. The etching process removes the interlevel dielectric layer 134 at the exposed locations. Portions of the interlevel dielectric layer 134 remain below the mask the layer 144. After removal of the interlevel dielectric layer 134 at the exposed locations, the etching process selectively etches the gate spacer layer 132 in the downward direction for a selected duration of time. The duration is selected to ensure that vertically thinner portions of the exposed dielectric spacer layer 132 are entirely removed, while vertically thicker portions of the dielectric spacer layer 132 are not entirely removed. The result is that the interlevel dielectric layer 122 is exposed in the locations at which the dielectric spacer layer 132 is entirely removed, while portions of the dielectric spacer layer 132 remain on the recess surfaces of the dielectric helmet structures 117 and on sidewalls of the gate dielectric 110. In some embodiments, the exposed lower portions of sidewalls of the dielectric spacer layer 132 are aligned with sidewalls of the dielectric liner layer 120.

In FIG. 1J, the mask layer 144 has been removed, in accordance with some embodiments. The view of FIG. 1J further illustrates the positions and shapes of the remaining portions of the dielectric spacer layer 132, the source/drain isolation structures 142, the interlevel dielectric layer 134, the interlevel dielectric layer 122, and the dielectric liner layer 120.

In FIG. 1K, an etching process has been performed, in accordance with some embodiments. The etching process removes the exposed portions of the interlevel dielectric layer 122 in the trenches 147. The etching process also selectively etches the dielectric liner layer 120 in the downward direction. The result is that exposed portions of the etch-stop dielectric layer 120 that are vertically thin are entirely removed, thereby exposing the top surface of the source/drain regions 112. Vertically thicker portions of the etch-stop dielectric layer 120 and dielectric spacer layer 132 are not entirely removed.

In some embodiments, the etching process also etches exposed portions of the source/drain regions 112. In other words, the exposed portions of the top surface of the source/drain regions 112 are recessed with respect to the top surface of the source/drain regions that are still covered by the dielectric liner layer 120. In FIG. 1K, the inner spacers 114 that are highest in the vertical direction Z have been labeled 114h. In some embodiments, the source/drain regions 112 are recessed below a level of the top surface of the highest inner spacers 114h, or even entirely below the highest inner spacers 114h. The etching process that etches the source/drain regions 112 can include an isotropic etching process. The isotropic etching process can etch both the dielectric liner layer 120 (which previously acted as an etch stop layer) and the source/drain regions 112. The isotropic etching process can also act as a precleaning process that removes byproducts prior to formation of a silicide layer on the source/drain regions 112. The etching process is a low aspect ratio and forms a shallow source/drain contact location.

The result of the etching process is a U-shaped recess 145 in the source/drain regions 112. The U-shaped recess 145 is symmetrical with respect to the gate metals 108a and 108b. In other words, the arm portions of the U-shaped recess are equidistant from the respective gate metals 108a and 108b.

In FIG. 1L, a silicide layer 149 and source/drain contacts 150 have been formed, in accordance with some embodiments. Prior to formation of the source/drain contacts 150, the silicide layer 149 is formed on exposed surfaces of the source/drain regions 112. In particular, the number portion of the source/drain regions 112 forms a U shape. The silicide 149 is formed on exposed surfaces of the U shape portion of the source/drain regions 112. The silicide 149 also has a U shape. The silicide 149 acts as an interface between the semiconductor material of the source/drain regions 112 and the source/drain contacts 150. The silicide 149 includes both the semiconductor material of the source/drain region 112 and a metal. As such, the silicide 149 may include titanium silicide, molybdenum silicide, zirconium silicide, Sb silicide, nickel silicide, tungsten silicide, ruthenium silicide, or other types of silicide. The silicide 149 is highly conductive compared to the source/drain regions 112.

The source/drain contacts 150 are formed by depositing one or more layers of conductive material in the trenches 147. The one or more layers of conductive material fill the recess in the source/drain region 112 and are in direct contact with the silicide layer 149. When the one or more layers of conductive material are deposited for the source/drain contacts 150, the one or more layers of conductive material initially entirely fill the trenches 147 and cover the top surfaces of the dielectric spacer layer 132 and the source/drain isolation structures 142. The one or more layers of conductive material for the source/drain contacts 150 can be deposited by PVD, ALD, CVD, or other suitable deposition processes. The source/drain contacts 150 can include tungsten, aluminum, titanium, copper, or other suitable conductive materials.

After deposition of the one or more layers of conductive material for the source/drain regions 150, a CMP process is performed. In some embodiments, the CMP process reduces the height of the one or more layers of conductive material for the source/drain regions 150, the dielectric spacer layer 132, the source/drain isolation structures 142, the upper portion of the gate metal 108, the dielectric helmet structure 117, and the dielectric liner layer 120.

One result of the CMP process is that the state source/drain regions 150 as shown in FIG. 1L are formed. In particular, because the portions of the conductive materials for the source/drain regions 150 are removed from the top surfaces of the source/drain isolation structures 142, the source/drain isolation structures 142 electrically isolate the source/drain contacts 150 for selected transistors separated from each other in the Y direction. A source/drain contact 150a is electrically coupled to the source/drain region 112a of the transistor 104a. A source/drain contact 150ab is electrically coupled to the shared source/drain region 112ab of the transistors 104a and 104b, and a source/drain region 150b is electrically coupled to the source/drain region 112b of the transistor 104b. As can be seen in FIG. 1L, a source/drain isolation structure 142 electrically isolates the source/drain region 150b from a source/drain contact adjacent in the Y direction.

Another result of the CMP process is that the upper portions of the gate metals 108 are entirely removed from the top surface of the dielectric helmet structures 117. Now, the upper portion of the gate electrodes 108 has a top surface that is coplanar with the top surface of the dielectric helmet structure 117. Furthermore, the top surface of the dielectric liner layer 120, the dielectric spacer layer 132, the gate dielectric 110, the gate metal 108, the source/drain contacts 150, and the gate isolation structures 123 are all coplanar.

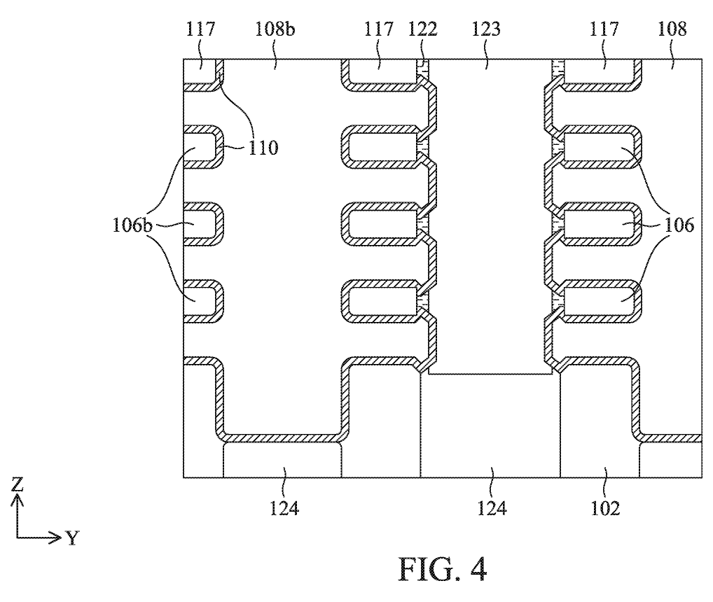

Referring back to FIG. 1A, when the gate metal 108 was initially formed, the upper portion of the gate metal 108 was patterned as stripes extending in the Y direction. A portion of the gate metal 108 was positioned directly above the dielectric helmet structures 117. Though not apparent in FIG. 1A, the gate metal 108 also wraps around the dielectric helmet structures 117 at this stage of processing. With reference again to FIG. 1L, when the CMP process of FIG. 1L is performed, the portion of the gate metal that is directly above the dielectric helmet structures 117 is entirely removed. Accordingly, another result of the CMP process is that the highest portion of the gate metal 108 is now laterally offset in the Y direction from the portions of the gate metals 108 that are directly above the channels 106. The dielectric spacer layers 132 now act as sidewall spacers between the upper portions of the gate metal 108 and adjacent source/drain contacts 150. Furthermore, the position of the gate metal 108 and the lateral offset of the highest surface of the gate metal 108 relative to the channels 106 is further clarified in the cross-sectional view of FIG. 4, taken along cut lines 4 of FIG. 1L.

Another result of the processes described above, is that some of the source/drain contacts 150 have portions of differing widths in the X direction. For example, a first narrow portion of the source/drain contact 150 has a dimension D1 between 8 nm and 20 nm. A second wider portion of the source/drain contact 150 has a dimension D2 with a width between 12 nm and 24 nm. Other dimensions can be utilized without departing from the scope of the present disclosure. The portion of the source/drain contact 150 with the with D1 is bounded by and in direct contact with the dielectric liner layer 120. The portion of the source/drain contact with the width D2 is bounded by and in direct contact with the dielectric spacer layer 132.

The source/drain contacts 150 correspond to metal structures by which voltages are applied to the source/drain regions 112. The source/drain contacts 150 can include tungsten, aluminum, titanium, copper, or other suitable conductive materials. The source/drain contacts 150 are positioned on the vertical sidewalls of the silicide layer 149. The source/drain contacts 150 are in direct contact with the silicide 149.

In some embodiments, as described previously, the dielectric helmet structures 117 are absent. In this case, the upper portion of the gate metal 108 and the dielectric spacer layer 132 are in place of the dielectric helmet structure 117.

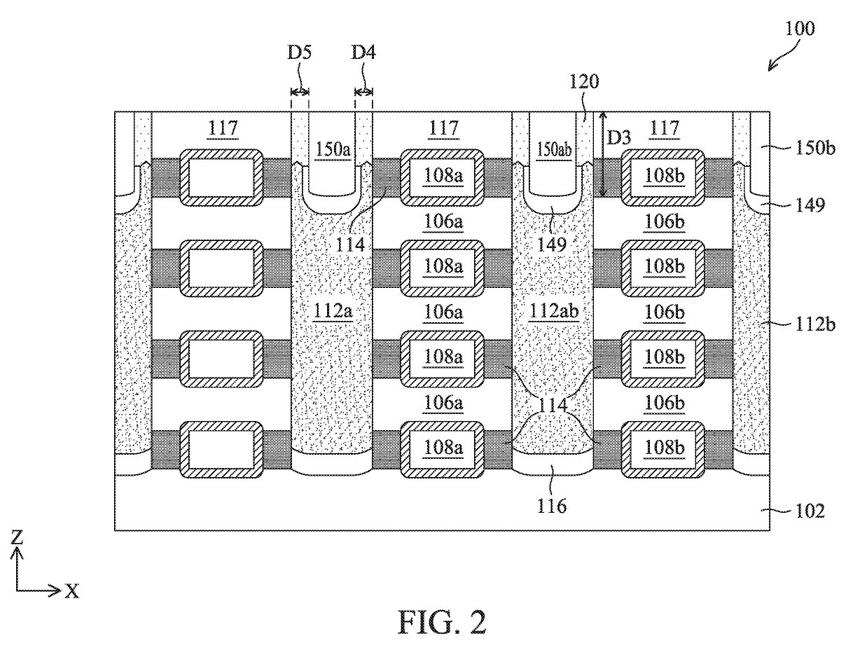

FIG. 2 is a cross-sectional view of the X-Z face of the integrated circuit 100 of FIG. 1L, in accordance with some embodiments. In some embodiments, the source/drain contacts 150 have a height dimension D3 between 6 nm and 36 nm. Other dimensions can be utilized without departing from the scope of the present disclosure.

The process described above for forming the source/drain contacts 150 results in symmetric source/drain regions 150 in the sense that they are centered between adjacent features. As one example, a right side of the source/drain contact 150a is separated from the adjacent dielectric helmet structure 117 by a dimension D4, while the left side of the source/drain region 150 a is separated from the adjacent dielectric helmet structure 117 by a dimension D5. In some embodiments, D4 and D5 or equal to each other due to the symmetric centering of the source/drain contact 150. As set forth previously, the dielectric helmet structures 117 may not be present in some embodiments, accordingly, the symmetric positioning of the source/drain contacts 150 results in sidewalls of the source/drain contact 150 having a same distance between adjacent features such as a gate metal, a gate spacer, or other features.

FIG. 2 also illustrates that the source/drain contact 150 extends into the U-shaped area of the source/drain region 112. Accordingly, a portion of the source/drain region 112 is positioned between the source/drain contact 150 and the adjacent portion of the gate metal 108 on each side of the source/drain region 112. A portion of the silicide 149 is likewise positioned on sidewalls of the source/drain contact 150.

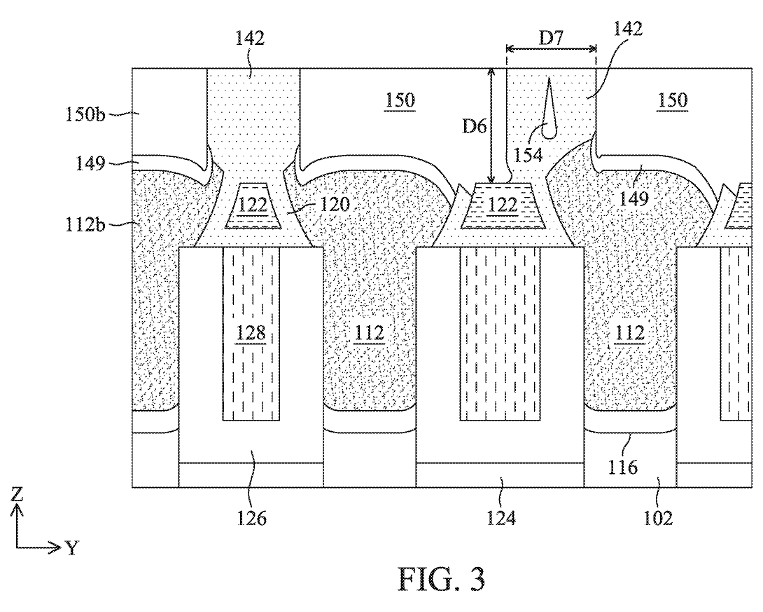

FIG. 3 is an enlarged side sectional view of the exposed Y-Z face of the integrated circuit 100 of FIG. 1L, in accordance with some embodiments. FIG. 3 illustrates that source/drain isolation structures 142 have a depth dimension D6 between 5 nm and 45 nm, though other dimensions can be utilized without departing from the scope of the present disclosure. As can be seen in FIG. 3, the source/drain isolation structures 142 directly contact the source/drain region 112, the dielectric liner layer 120, the interlevel dielectric layer 122, the silicide 149, and the source/drain contacts 150.

In some embodiments, the source/drain isolation structures 142 have a width dimension D7 in the Y direction between 8 nm and 30 nm, though other dimensions can be utilized without departing from the scope of the present disclosure. In some embodiments, the source/drain contacts 150 have a width dimension in the Y direction between adjacent source/drain isolation structures 142 between 8 nm and 300 nm, though other dimensions can be utilized without departing from the scope of the present disclosure.

Heretofore, the source/drain isolation structures 142 have been shown as a single dielectric layer. However, in practice, the source/drain isolation structures 142 may include multiple dielectric layers. For example, the source/drain isolation structures 142 may include a dielectric liner layer that lines the surfaces of structures contacted by the source/drain isolation structures 142. The source/drain isolation structures 142 may include a bulk deposition dielectric material in contact with the dielectric liner layer and filling the remaining space. The dielectric liner layer can include one or more of silicon oxide, silicon nitride, silicon oxynitride (SiON), SiOCN, SiCN, fluorine-doped silicate glass (FSG), or other suitable dielectric materials. The bulk deposition dielectric material of the source/drain isolation structures 142 can include silicon oxide, silicon nitride, silicon oxynitride (SiON), SiOCN, SiCN, fluorine-doped silicate glass (FSG), or other suitable dielectric materials. The material of the bulk deposition dielectric material and the dielectric liner layer can be different from each other.

In some embodiments, the source/drain isolation structures 142 can include a void or seam 154. The void or seam 154 can result from a conformal deposition process of the source/drain isolation structures 142 that may cause an upper portion of the source/drain isolation structures 142 to close off prior to filling of the bottom or lower portions of the source/drain isolation structures 142. The void or seam 154 may be filled with air, an inert gas such as N2 or Ar, or other fluids. In some cases, the void or seam may substantially be a vacuum.

FIG. 4 is a cross-sectional view of the integrated circuit 100 of FIG. 1L, taken along cut lines 4, in accordance with some embodiments. FIG. 4 illustrates the shape of the gate metal 108b in relation to the channels 106. While FIG. 4 illustrates the gate metal 108b substantially on three sides of the channels 106 due to the presence of the gate isolation structure 123, in some embodiments the gate metal 108b wraps around all sides of the channels 106. In these cases, the gate isolation structure 123 may have a reduced width in the Y direction such that the gate metal 108 can wrap all the way around the channels 106. The gate metal 108a can have a substantially similar shape as the gate metal 108b shown in FIG. 4.

In some embodiments, the dielectric helmet structure 117 is present. The dielectric helmet structure 117 is separated from the gate isolation structure 123 buy remnant of the interlevel dielectric layer 122. However, as set forth previously, in some cases the dielectric helmet structure 170 may not be present. The gate metal 108 may fill the space occupied by the dielectric helmet structures 117.

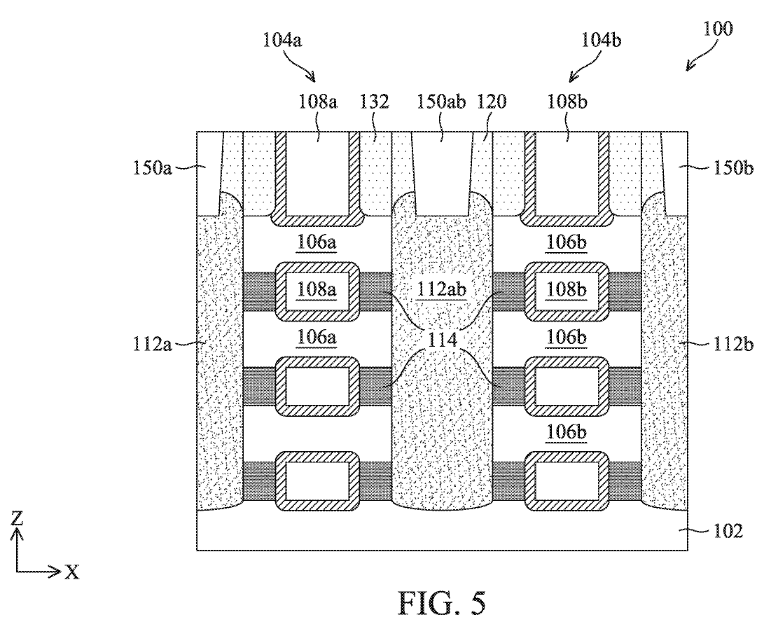

FIG. 5 is a cross-sectional view of an integrated circuit 100, in accordance with some embodiments. The integrated circuit 100 is a variation of the integrated circuit 100 of FIG. 1L, in accordance with some embodiments. The integrated circuit 100 of FIG. 5 includes most of the same structures as FIG. 1L utilizing the same reference numbers and will not be described in detail again. In FIG. 5, the dielectric helmet structures 117 are not formed, in accordance with some embodiments. Accordingly, the upper portion of the gate metal 108 is directly above the corresponding channels 106. The source/drain contacts are symmetrically positioned between adjacent gate metals 108, similar as in FIG. 1L. Furthermore, a recess is formed in the source/drain regions 112 utilizing the dielectric spacer layer 132 and the dielectric liner layer 120 for alignment without the use of the hard mask or stringent photolithography processes. Accordingly, the integrated circuit 100 of FIG. 5 provides substantially similar benefits as described previously.

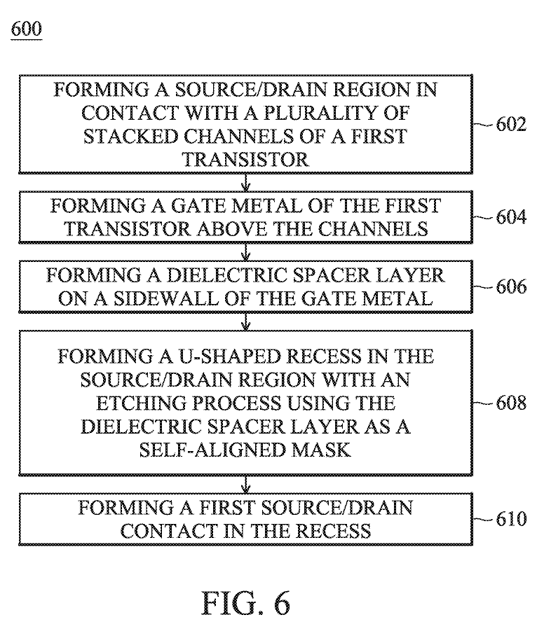

FIG. 6 is a flow diagram of a method 600 for forming an integrated circuit, in accordance with some embodiments. The method 600 can utilize processes, components, and systems described in relation to FIGS. 1-5. At 602, the method 600 includes forming a source/drain region in contact with a plurality of stacked first channels of a first transistor. One example of a first transistor is the first transistor 104a of FIG. 1L. One example of a source/drain region is the source/drain region 112ab of FIG. 1L. One example of stacked channels is the stacked channels 106a of FIG. 1L. At 604, the method 600 includes forming a gate metal of the first transistor above the channels. One example of a gate metal is the gate metal 108a of FIG. 1L. At 606, the method 600 includes forming a dielectric spacer layer on a sidewall of the gate metal. One example of a dielectric spacer layer is the dielectric spacer layer 132 of FIG. 1C. At 608, the method 600 includes forming a U-shaped recess in the source/drain region with an etching process using the dielectric spacer layer as a self-aligned mask. One example of a U-shaped recess is the recess 145 of FIG. 1K. At 610, the method 600 includes forming a first source/drain contact in the recess. One example of a source/drain contact is the source/drain contact 150ab of FIG. 1L.

Embodiments of the present disclosure provide an integrated circuit with nanostructure transistors having improved performance. The nanostructure transistors each have a plurality of stacked channels formed over a substrate. Each nanostructure transistor includes source/drain regions in contact with the channels. Source/drain contacts are formed in a self-aligned manner within recesses formed in the source/drain regions. The self-aligned process utilizes dielectric spacer layers on sidewalls of engaging gate metals as a mask to form the recesses. The source/drain contacts are then formed in the recesses. Due to the self-aligned process, the source/drain contacts are symmetrically positioned between adjacent gate metals.

The configuration of the source/drain regions and the source/drain contacts provides several benefits. First, the self-aligned process avoids the possibility that the source/drain contact with short circuit with the gate metals. Second, the self-aligned process results in very relaxed photolithography standards when forming source/drain contacts. Furthermore, source/drain isolation structures can be formed prior to forming the source/drain contacts. These factors collectively result in better wafer yields, integrated circuits with better electrical performance, and fewer scrapped wafers.

In one embodiment, a method includes forming a source/drain region in contact with a plurality of stacked channels of a first transistor, forming a gate metal of the first transistor above the channels, and forming a dielectric spacer layer on a sidewall of the gate metal. The method includes forming a U-shaped recess in the source/drain region with an etching process using the dielectric spacer layer as a self-aligned mask and forming a first source/drain contact in the recess.

In one embodiment, a device includes a first transistor. The first transistor includes a first source/drain region, a plurality of stacked first channels in contact with the first source/drain region, and a first gate metal above the stacked first channels. The device includes a second transistor. The device includes a plurality of stacked second channels in contact with the first source/drain region, a second gate metal above the stacked second channels, and a first source/drain contact electrically coupled to the first source/drain region and positioned between the first gate metal and the second gate metal in a recess in the source/drain region.

In one embodiment, a device includes a first transistor. The first transistor includes a first source/drain region, a plurality of stacked first channels in contact with the first source/drain region, and a first gate metal above the stacked first channels. The device includes a dielectric helmet structure above the highest channel, a dielectric spacer layer on a sidewall of the gate metal and abutting the dielectric helmet structure, and a source/drain contact electrically coupled to the source/drain region. A top surface of the first gate metal, a top surface of the dielectric helmet structure, a top surface of the dielectric spacer layer, and a top surface of the source/drain contact are coplanar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a source/drain region in contact with a plurality of stacked channels of a first transistor;
depositing a gate metal of the first transistor wrapped around the channels and positioned above the channels between a pair of gate spacers;
replacing at least a portion of the gate spacers with a dielectric spacer layer on a sidewall of the gate metal;
patterning the dielectric spacer layer to form an opening above a top surface of the source/drain region;
forming a recess in the source/drain region with an etching process using the dielectric spacer layer as a mask; and
forming a first source/drain contact in the recess.

2. The method of claim 1, comprising:
prior to forming the first source/drain contact, forming a source/drain isolation structure in contact with the dielectric spacer layer;
forming the first source/drain contact by depositing a conductive material in the recess, on the dielectric sidewall spacer, and on the source/drain isolation structure; and
electrically isolating the first source/drain contact from a second source drain contact of a second transistor by planarizing a top surface of the first source/drain region with a top surface of the source/drain isolation structure.

3. The method of claim 2, wherein forming the source/drain isolation structure includes exposing a portion of the first source/drain region by forming a trench in an interlevel dielectric layer above the first source/drain region and depositing a dielectric material of the source/drain isolation structure in contact with the first source/drain region in the trench.

4. The method of claim 2, wherein a top surface of the first source/drain contact has a first lateral width in a first direction at a first end of the source/drain region and a second lateral width in the first direction at a second end of the source/drain region, wherein the second width is greater than the first width.

5. The method of claim 2, wherein the source/drain isolation structure includes a void between the first and second source/drain contacts.

6. The method of claim 1, wherein the etching process is an isotropic etching process.

7. The method of claim 1, comprising:
forming a first dielectric helmet structure of the first transistor above a highest channel of the plurality of channels; and
forming a second dielectric helmet structure of a second transistor having a plurality of second channels in contact with the source/drain region, wherein the first source/drain contact is positioned equidistant between the first and second dielectric helmet structures.

8. The method of claim 7, wherein a top surface of the gate metal is coplanar with a top surface of the dielectric helmet structure.

9. The method of claim 7, comprising:
forming a portion of the first gate metal and a gate dielectric of the first transistor on the first dielectric helmet structure;
forming the dielectric spacer layer on a top surface of the first dielectric helmet structure and on a top surface of the first gate metal; and
forming the recess in the first source/drain region by etching through portion of the dielectric spacer layer above the first source/drain region.

10. The method of claim 9, comprising, after forming the first source/drain contact, making a top surface of the first dielectric helmet structure, a top surface of the dielectric spacer layer, a top surface of the first gate metal, and a top surface of the first source/drain contact coplanar by performing a planarization process.

11. The method of claim 1, comprising:
removing the gate spacer layers after forming the gate metal; and
forming the dielectric spacer layer on a top surface of the gate metal after removing the sacrificial sidewall spacers.

12. A device, comprising:
a source/drain region;
a plurality of stacked channels;
a dielectric helmet structure above the stacked channels;
a gate metal above the stacked channels;
a gate dielectric layer on sidewalls of the gate metal; and
a dielectric spacer layer in contact with a sidewall of the dielectric helmet structure and the gate dielectric.

13. The device of claim 12, further comprising a source/drain contact extending into a U-shaped recess in the source/drain region to couple to the source/drain region.

14. The device of claim 13, wherein a first portion of the source/drain region is positioned between the source/drain contact and the gate metal, wherein a second portion of the source/drain region is positioned between the source/drain contact and a second gate metal.

14. The device of claim 13, comprising a dielectric spacer layer on a sidewall of the first gate metal and on a sidewall of the second gate metal, wherein the recess in the first source/drain region is aligned with the dielectric spacer layer.

15. The device of claim 13, wherein a top surface of the gate metal, a top surface of the dielectric spacer layer, and a top surface of the dielectric helmet structure are coplanar.

16. The device of claim 13, further comprising a dielectric liner layer in contact with the dielectric helmet structure and the source/drain contact

17. The device of claim 15, further comprising a U-shaped silicide between the source/drain contact and the source/drain region.

18. A method, comprising:
forming a dielectric helmet structure above a plurality of stacked channels;
forming a source/drain region in contact with the channels;
depositing a gate metal above the stacked channels;
depositing a dielectric spacer layer on a sidewall of the gate metal and abutting the dielectric helmet structure;
depositing a source/drain contact electrically coupled to the source/drain region, wherein a top surface of the gate metal, a top surface of the dielectric helmet structure, a top surface of the dielectric spacer layer, and a top surface of the source/drain contact are level.

19. The method of claim 18 further comprising removing a gate spacer and replacing the gate spacer with the dielectric spacer layer.

20. The device of claim 18, wherein the source/drain contact is positioned in a U-shaped recess in the source/drain region.
